(19) United States
(12) Patent Application Publication
(10) Pub. No.: US 2024/0383731 A1
(43) Pub. Date: Nov. 21, 2024

(54) HANDLING DEVICE AND ROBOTIC SYSTEM FOR EXCHANGING COMPONENT FEEDERS AT A PICK AND PLACE STATION

(71) Applicant: ASMPT GmbH & Co. KG, Munich (DE)

(72) Inventors: Christoph FISCHER, Geretsried (DE); Johannes JUSTINGER, Landsberg am Lech (DE); Ming Chen LIM, Singapore (SG); Christian MACK, Unterhaching (DE); Matthias MIKSCH, Munich (DE); Vincent PFEIFER, Munich (DE); You Jian TEOH, Singapore (SG)

(21) Appl. No.: 18/660,765

(22) Filed: May 10, 2024

(30) Foreign Application Priority Data
May 17, 2023 (DE) 10 2023 113 078.1

(51) Int. Cl. B66F 9/06; B66F 9/075; B66F 9/12; B66F 9/18; H05K 13/02

(52) U.S. Cl. CPC B66F 9/063; B66F 9/0755; B66F 9/122; B66F 9/18; H05K 13/021

(57) ABSTRACT

A handling device (100) for automatically exchanging component feeders (390) at a pick and place station (4000) for assembling component carriers with electronic components is described. The handling device (100) comprises (a) a chassis (110); (b) a drive (120) with a stationary drive component (122) attached to the chassis (110) and a movable drive component (126) which can be spatially positioned along a y-direction; (c) a first coupling device (130a) which is attached to the movable drive component (126) and which has a first coupling element (234) and a first actuator (232); (d) a second coupling device (130b), which is also attached to the movable drive component (126) and which comprises a second coupling element (234) and a second actuator (232); and (e) a control device (102), which is configured to individually actuate the first actuator (232) and to individually actuate the second actuator (232). The first coupling element (234) is configured to couple with a first component feeder (190a) when the first actuator (232) is actuated, and the second coupling element (234) is configured to couple with a second component feeder (190b) when the second actuator (232) is actuated. Furthermore, a robotic system (150) with such a handling device (100) is described.

### TECHNICAL FIELD

The present invention in general pertains to the technical field of placement technology. More specifically, the present invention pertains to a handling device for exchanging component feeders at a pick and place station and to a robotic system with such a handling device.

### BACKGROUND OF THE INVENTION

Component carriers such as printed circuit boards or substrates are populated with electronic components using pick and place machines. A pick and place machine has a placement head which (i) picks up electronic components at a pick-up position of a component feeder, (ii) transports them in a placement area of the pick and place machine in which the component carrier to be placed is located, and (iii) places the picked-up component on the component carrier at a predetermined placement position.

A pick and place machine can have one or more pick and place stations, whereby a pick and place station typically has a placement head and a gantry system for positioning the placement head as well as several component feed tracks. A component feeder can be attached to each component feed track, with which a specific type of component is provided to the placement process in each case.

In order to ensure that the operation of a pick and place machine is as uninterrupted as possible, it must be ensured that a sufficient quantity of electronic components is always available for each component feed track. Currently, the continuous supply of components to the feed tracks involves the so-called splicing of a component belt in which electronic components are packaged. In a splicing process, the end of a component belt, which is about to be used up due to the removal of components, is connected to the beginning of a new component belt by means of a connecting element. Such splicing is typically carried out manually by an operator.

In order to automate the “subsequent delivery” of components to a feed track, it is known not only to provide a new component belt on a component feed track (and to connect it to the “old” component belt by means of a splicing process). Instead, an entire “old component feeder” together with an “old” or at least partially “used” component belt can also be exchanged with a “new component feeder” with a “new” or at least partially “unused” component belt.

In order to be able to carry out this exchanging process reliably, component feeders with a housing containing a component belt wound onto a belt reel have been proposed. A component replenishment process at a component feed track of a pick and place machine is then carried out by automatically exchanging the entire component feeder directly at the pertaining feed track.

The automated exchanging is carried out with a robot or an automatic handling device, with which a “used” or “old” component feeder is removed from the pertaining feed track and then an “unused” or “new” component feeder is placed on the pertaining feed track.

The basic idea of automatically exchanging entire component feeders is described in WO 2022 230054 A1. This document discloses a driverless transport and handling system with a driverless transport vehicle (Automated Guided Vehicle, AGV) and a handling device attached thereto (i) for automatically transporting component feeders and (ii) for automatically handling component feeders. The handling comprises an automatic removal of component feeders from a storage for component feeders and an automatic storage of component feeders in the storage. Details of the mechanical or structural design of the handling system described are not disclosed in WO 2022 230054 A1.

The invention is based on the task of creating a handling system for the automatic exchanging of component feeders on the feed tracks of an automatic pick and place machine, which enables a rapid exchanging of several component feeders and yet can be implemented in a simple and cost-effective manner.

### SUMMARY OF THE INVENTION

This object is achieved by the subject matter of the independent claims. Advantageous embodiments of the present invention are described in the dependent claims.

According to a first aspect of the invention, a handling device for automatically exchanging component feeders at a pick and place station for automatically placing electronic components on component carriers is described. The handling device described has (a) a chassis; (b) a drive with a stationary drive component attached to the chassis and a drive component which can be spatially positioned along a y-direction; (c) a first coupling device which is attached to the movable drive component and which has a first coupling element and a first actuator; (d) a second coupling device which is also attached to the movable drive component and which has a second coupling element and a second actuator; and (e) a control device which is configured for individually actuating the first actuator and for individually actuating the second actuator. According to the invention, the first coupling element is arranged to couple with a first component feeder when the first actuator is actuated. Furthermore, the second coupling element is set up to couple with a second component feeder when the second actuator is actuated.

The y-direction mentioned here represents the “main” direction of movement of the component feeder to be exchanged. This means that the “old” component feeder is removed from the pick and place station along the y-direction and that the “new” component feeder is brought to the pick and place station along this y-direction (in the opposite direction).

The handling device described is based on the insight that handling of a plurality of at least two component feeders can also be carried out by a single drive as part of an exchanging of at least one component feeder, which is responsible for moving the component feeders involved in the exchanging both (i) along a removal direction away from the pick and place station or from a component feed system assigned to the pick and place station and (ii) along an insertion direction towards the pick and place station or towards the component feeder. The insertion direction is parallel to the said y-direction and the removal direction is anti-parallel to the said y-direction.

According to the invention, only one such y-drive is sufficient for the handling device described, because instead of at least one further y-drive, which is required in known handling devices for the automatic exchanging of component feeders, a coupling device provided individually for precisely this component feeder is provided for each component feeder that is to be handled. As a result, precisely this component feeder is coupled to the movable drive component upon corresponding individual activation and, if necessary, moved by the y-drive together with one or more other component feeders that are also coupled. In an operating state in which two or more component feeders are to be exchanged, two or more “old” component feeders can be removed simultaneously from the pick and place station or from a component feed system assigned to the pick and place station. The same naturally also applies to the addition of “new” component feeders. This means that several component feeders can be exchanged at the same time, which results in a considerable advantage in terms of time compared to a sequential exchanging of component feeders, i.e. one component feeder is replaced after the other component feeder, which can be used profitably to increase the productivity of the pertaining pick and place station.

In accordance with the invention, the handling device described thus dispenses with a further y-drive. As a result, it is possible to build the described handling device in a cost-effective manner.

The drive described is or comprises (precisely) a linear drive. According to the invention, however, it is not excluded that the drive also has at least one further degree of freedom of movement or drives the movable drive component along this further degree of freedom of movement. The drive can also comprise several “sub-drives” that are assigned to different directions of movement.

In addition to the two drive components mentioned, i.e. the stationary drive component and the movable drive component, the drive can also have a motorized drive component, which ensures automatic joint movement of all coupling devices when suitably controlled. The motorized drive component can, for example, be an electric motor and in particular an electric linear motor.

The two coupling elements can have any suitable spatial physical structure which is suitable for establishing a direct or indirect mechanical coupling between the respective coupling device and the pertaining component feeder. Alternatively, or in combination, the two coupling elements may also establish a magnetic coupling between the respective coupling device and the pertaining component feeder. Such a magnetic coupling can be achieved by means of a magnetic coupling element that can be mechanically adjusted between at least two positions and/or via an electromagnet that can be activated.

According to an exemplary embodiment of the invention, the first coupling element has a first engagement element which is configured to be brought into engagement by the first actuator with a complementary first engagement element on the first component feeder. Further, the second coupling element has a second engagement element configured to be engaged by the second actuator with a complementary second engagement element on the second component feeder.

The mechanical coupling via engagement elements described with this exemplary embodiment can be implemented in a particularly simple and also cost-effective manner in terms of design and still ensure a reliable coupling between the components involved when actuated accordingly.

The engagement elements involved in the mechanical coupling can have any geometric structure that is suitable for establishing a reliable mechanical connection by means of mechanical bond. In such an engagement, it does not matter which engagement element engages or penetrates the other engagement element. This means that it does not matter whether the first/second engagement element has a protrusion, for example, and penetrates into an opening or engages behind another structure, such as an edge, of the complementary first/second engagement element. The protrusion can also be associated with the complementary first/second engagement element and the opening or the edge can also be associated with the first/second engagement element.

According to a further exemplary embodiment of the invention, the coupling directions are arranged next to each other along an x-direction, wherein the x-direction is angular and in particular perpendicular to the y-direction. This enables a spatially compact arrangement of the first coupling direction, the second coupling direction and possibly further coupling devices. The entire handling device can thus also be built within a compact design in a favorable manner, at least along the y-direction.

According to a further exemplary embodiment of the invention, the drive further comprises a movable intermediate component which, together with the stationary drive component and the movable drive component, forms a telescopic system.

The described telescopic embodiment of the (common) drive can bring about a favorable extension of the distance covered by the movable drive component. In particular, this distance (along the y-direction) can be longer than the spatial dimension of the entire handling device along the y-direction.

The telescopic system can be implemented in a wide variety of ways. As examples, belt, gear and/or spindle drive mechanisms are mentioned here.

According to a further exemplary embodiment of the invention, the first coupling device further comprises a further first coupling element which is spatially spaced along the y-direction from the first coupling element, wherein the further first coupling element is configured to couple (i) upon actuation of the first actuator or (ii) upon actuation of a further first actuator of the first coupling device with the first component feeder. As an alternative or in combination, the second coupling device further comprises a further second coupling element which is spatially spaced along the y-direction from the second coupling element, wherein the further second coupling element is configured to couple (i) upon actuation of the second actuator or (ii) upon actuation of a further second actuator of the second coupling device with the second component feeder.

The further first coupling element described can cooperate with the first coupling element such that, when the first actuator attached to the movable drive component and optionally the further first actuator are displaced, the first coupling element is responsible for displacing the first component feeder along a first partial section of the entire first displacement section of the first component feeder. The second coupling element is then responsible for displacing the first component feeder along a further first partial section of the entire first displacement section of the first component feeder. The two partial sections have a certain overlap, which makes it possible for the first coupling element and the further first complement to be re-engaged when the first component feeder is in a predetermined position along the entire first displacement section. For example, as soon as the component feeder has reached the predetermined position after a displacement by the movable drive component along the first partial section in which the component feeder is coupled with the first coupling element, this coupling with the first coupling element is canceled. Both first coupling elements are then displaced (by the movable drive component of the drive) so that the further first coupling element can couple with the first component feeder. After coupling of the further first complement with the first component feeder, both first coupling elements are then displaced again so that the first component feeder covers the further first partial section.

The above-described re-engagement between the first coupling element and the further first coupling element naturally also applies in a corresponding manner in relation to the second component feeder. In this case, the second component feeder is initially displaced along its entire second displacement section along a second partial section of the entire second displacement section along the y-direction when coupled to the second coupling element. After a re-engagement from the second coupling element to the further second coupling element, the second component feeder is then moved along the further second partial section of the entire second displacement section when coupled to the further second complement.

It is hereby emphasized that the described re-engagement between the pertaining coupling element and the pertaining further coupling element can take place, and in most applications does take place, both when the pertaining component feeder is moved (i) along a removal direction away from the pick and place station or from a component feed system associated with the pick and place station and (ii) along an insertion direction towards the pick and place station or towards the component feed system.

The re-engagement described here has the advantage that the total displacement section that the pertaining component feeder can cover can be significantly longer, and specifically up to a factor of two longer than the distance traveled by the movable drive component. In particular, this displacement section (along the y-direction) can be longer than the spatial dimension of the entire handling device along the y-direction.

According to a further exemplary embodiment of the invention, the handling device further comprises a third coupling device, which is also attached to the movable drive component and which comprises a third coupling element and a third actuator. In this exemplary embodiment, the control device is also configured to individually actuate the third actuator. Furthermore, the third coupling element is configured to couple with a third component feeder when the third actuator is actuated.

The embodiment described here with a third coupling device has the advantage that not just two but three component feeders can be handled simultaneously. This can increase the efficiency when exchanging component feeders such that the entire exchanging process can be carried out quickly, thus reducing undesirable non-productive downtimes during the assembly of a large number of component carriers.

It should be noted that there are also embodiments in which the handling device has more than three, for example four, six or ten or even more coupling devices, so that a maximum corresponding number of component feeders can be handled simultaneously. In this context, it should be noted that two component feeders are typically involved and must be dealt with when exchanging a component feeder. One component feeder is an “old component feeder”, which is removed from the pick and place station or from a component feed system assigned to the pick and place station. The other component feeder is a “new component feeder”, which is added to the pick and place station or a component feed system assigned to the pick and place station.

According to a further exemplary embodiment of the invention, the handling device further comprises a support structure for supporting the first component feeder and/or the second component feeder and/or the third component feeder. The support structure described can have any shape or geometry that allows the component feeders to rest on it. This means that the height position of the respective component feeder can be precisely defined. This applies at least when the component feeder is held by the handling device or is handled by it. The support structure can be a support table, for example, although it is not absolutely necessary for this support table to have a flat surface.

In particular, the component feeders can be moved along the surface of the support structure in the y-direction. In doing so, the pertaining component feeder can slide or slide along this surface. A guiding structure, for example a rail, can be used if necessary to move the pertaining component feeder along a precisely defined displacement path along the y-direction. Pulleys or other friction-reducing materials, which preferably have low abrasion, can also be used to reduce the friction between the pertaining component feeder and the support structure.

The described support structure can be a component of the aforementioned chassis. Alternatively or in combination, the support structure can also be connected directly or indirectly to this chassis in a spatially fixed manner.

According to a further aspect of the invention, a robotic system is described which comprises (a) a driverless transport vehicle; (b) a mechanical support structure which is attached to the driverless transport vehicle; and (c) a handling device of the type described above, wherein the handling device is attached (directly or indirectly) to the mechanical support structure.

The robotic system described is based on the insight that the handling device described above can be attached to a driverless transport vehicle and that this makes it possible to position the handling device in a simple manner along all those spatial directions along which the driverless transport vehicle can be moved on a floor surface. In particular, the handling device can thus also be positioned parallel to an x-direction along which various feed tracks of a pick and place machine are arranged. In this way, a suitable x-positioning of the handling device can ensure that exactly the “old” component feeder that is actually to be exchanged is removed with a predetermined coupling device. After removing the “old” component feeder, the handling device can then be moved along the x-direction such that a “new” component feeder is added precisely to the feed track of the pick and place station or a component feed system assigned to the pick and place station where the “old” component feeder was previously still present.

The driverless transport vehicle can also be used to position the described handling device parallel to a floor surface of a factory hall as required. For this purpose, it is only necessary for the driverless transport vehicle to be driven to the respective position in the factory hall. In particular, it is possible to retrieve one or more “new” component feeders from a temporary storage area and transfer them to a pick and place station where the component feeders are to be exchanged. During this exchanging, the “new” component feeders taken from the temporary storage then replace the “old” component feed systems located at the pertaining pick and place station or at a component feeder assigned to the pick and place station.

The driverless transport vehicle can be a conventional transport vehicle, which can also be used for a variety of other applications. This means that commercially available components can be used to implement the robotic system described. An application-specific development of the driverless transport vehicle is therefore not necessary and the robotic system described can be implemented comparatively inexpensively.

According to a further exemplary embodiment of the invention, the robotic system also has a vertical drive with a stationary vertical drive component attached to the mechanical support structure and a movable vertical drive component attached to the handling device, which is displaceable relative to the stationary vertical drive component along a vertical z-direction.

The vertical drive described has the advantage that the handling device and thus also the component feeders handled by the handling device can be brought to a predetermined height at which the component feeders can then be exchanged merely by a horizontal movement of the component feeders involved along the y-direction. Thus, the described handling device only has to activate one degree of freedom of movement for the component feeders involved, namely a displacement along the y-direction. As a result, the handling device can be implemented in a mechanically simple and cost-effective manner. The other degrees of freedom of movement required for an exchanging of component feeders can be provided by the driverless transport vehicle.

In some embodiments, the robotic system nevertheless has a further drive which is configured to move the described handling device relative to the driverless transport vehicle along a (horizontal) x-direction which is perpendicular to the said y-direction. A movement of the handling device along this degree of freedom of movement along the x-direction can then possibly also be implemented by a combination of an actuation of this further drive and a movement of the driverless transport vehicle along this x-direction.

According to a further exemplary embodiment of the invention, the vertical drive also has a motorized vertical drive component. Furthermore, in this embodiment, the movable vertical drive component has a coupling structure via which the movable vertical drive component is coupled to the motorized vertical drive component.

The motorized vertical drive component has the advantage that the height position of the handling device can be changed automatically when the motorized vertical drive component is controlled accordingly. Manual intervention by an operator is therefore not required to change the height position and the entire process of exchanging component feeders can be easily automated. The motorized vertical drive component can be an electric motor in the form of a rotary motor or an electric motor.

According to a further exemplary embodiment of the invention, the coupling structure comprises at least one support rod and/or at least one traction cable. This makes a particularly simple mechanical connection of the movable vertical drive component to the motorized vertical drive component as advantageous as possible. A simple mechanical connection has the advantage that (i) the motorized vertical drive component and (ii) the movable vertical drive component and thus also the handling device itself can be switched off independently of each other. This increases the degrees of freedom in the design implementation of the entire robotic system.

The support rod can be used to support the movable vertical drive component from below in a simple and reliable manner. In this case, the motorized vertical drive component can be located below the movable vertical drive component in particular. The traction cable can be used to hold the movable vertical drive component from above. In this case, the motorized vertical drive component is located above the movable vertical drive component in particular. Alternatively, the traction cable can also be deflected via a pulley so that the motorized vertical drive component can also be located below the movable vertical drive component in this case. In the case of a traction cable in particular, vertical guiding structures can still be provided, which can easily ensure precise vertical displacement of the handling device.

According to a further exemplary embodiment of the invention, the robotic system also has a positioning device which is attached directly or indirectly to the chassis of the handling device and which is designed in such a way that it (only) interacts with a complementary positioning device of the pick and place station (and/or the component feed system of a pick and place station) when the handling device is correctly positioned in relation to a pick and place station (and/or in relation to a component feed system of a pick and place station). This enables the handling device to be positioned correctly in an advantageous manner even before a component feeder is exchanged. This makes an important contribution to ensuring that such exchanging can be carried out reliably. In particular, for example, displacement of the pertaining component feeder can be reliably prevented during the linear jamming of the pertaining component feeder along the y-direction.

The interaction between the positioning device and the complementary positioning device can be of any nature. A few examples of this are electrical, magnetic and optical interactions. For all variants, a large number of suitable electronic, magnetic, optical, optoelectronic components are commercially available, which can be used by the person skilled in the art for a suitable implementation of the described positioning device and/or the described complementary positioning device.

In preferred exemplary embodiments, the positioning device described is attached to the support structure of the handling device described above.

It should be noted that the positioning system described, which comprises both the positioning device and the complementary positioning device, can be used both for positioning by the driverless transport vehicle and for positioning by the motorized vertical drive component described above. Of course, the described positioning system must be suitably designed with regard to the respective degrees of freedom of movement of these components of the robotic system.

According to a further exemplary embodiment of the invention, the positioning device and the complementary positioning device have mechanical positioning elements which come into mechanical contact and/or engagement with one another when the handling device is correctly positioned.

At least partial mechanical implementation of the positioning device (and the complementary positioning device) can represent a particularly simple but also effective way of ensuring correct positioning of the handling device for an exchanging. The mechanical interaction can merely be a mechanical stop that marks the end of a certain movement of the handling device. This can be useful, for example, for a movement along the y-direction caused by the driverless transport vehicle, so that the robotic system is positioned at the correct distance to the pick and place station (or to a component feed system of the pick and place station) along the y-direction before the component feeder is exchanged.

However, the mechanical interaction can also have a centering effect. It can be easily implemented by the complementary positioning device having at least one suitable inclined surface along which a part of the positioning device slides during positioning of the handling device and is thereby brought into a predetermined position. Alternatively or in combination, the positioning device of the robotic system described can also have at least one such inclined surface. Such centering can, for example, take place during a movement of the robotic system described or at least of the handling device along the y-direction and relate to directions perpendicular to the y-direction.

Further advantages and features of the present invention arise from the following exemplary description of currently preferable embodiments.

### BRIEF DESCRIPTION OF THE DRAWINGS

FIG. 1 shows a plan view of a handling device with a movable drive component to which four coupling devices are attached, so that four component feeders can be handled in a single operation.

FIG. 2 shows a perspective view of details of the coupling devices of a handling device for handling ten component feeders.

FIG. 3 shows a robotic system according to an exemplary embodiment of the invention.

FIGS. 4a to 4i illustrate the various steps involved in exchanging an “old” component feeder with a “new” component feeder.

### DETAILED DESCRIPTION

It is pointed out that, in the following detailed description, features or components of different embodiments that are identical or at least functionally identical to the corresponding features or components of another embodiment are provided with the same reference numerals or with reference numerals that are identical in the last two digits of the reference symbols of corresponding identical or at least functionally identical features or components. To avoid unnecessary repetitions, features or components that have already been explained on the basis of a previously described embodiment are no longer explained in detail at subsequent points.

Furthermore, it is noted that the following described embodiments only represent a limited selection of possible variations of embodiments of the invention. In particular, it is possible to combine the features of individual embodiments in a suitable manner, such that a multitude of different embodiments can be viewed as obviously disclosed for the person skilled in the art with the embodiments explicitly described here.

It is also noted that spatial terms such as “front” and “back”, “top” and “bottom”, “left” and “right”, etc. are used to describe the relationship of one element to another element or to describe other elements as illustrated in the figures. Accordingly, the spatial terms may apply to alignments that differ from the alignments shown in the figures. It is to be understood, however, that all such spatial terms refer to the alignments shown in the drawings for convenience of description and are not necessarily limiting, since the device, component, etc. shown in each case assume orientations which, when in use, may differ from the orientations shown in the drawing.

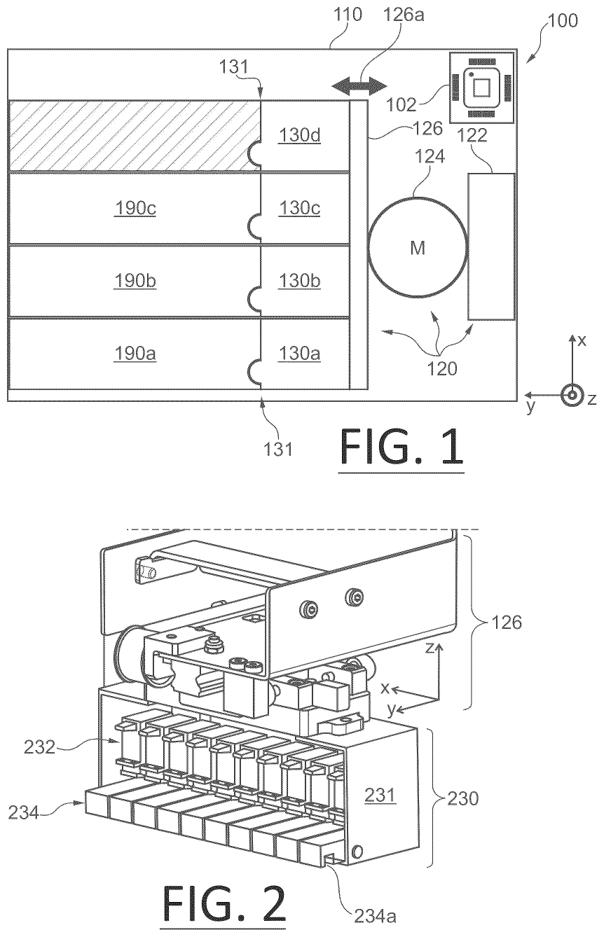

FIG. 1 shows a plan view of a handling device 100 according to an exemplary embodiment of the invention. The handling device 100 shown here has a chassis 110, which also serves as a frame structure of the handling device 100, to which various parts of the handling device, also not shown, are attached. Furthermore, the handling device 100 has a drive 120 which has a stationary drive component 122 attached to the chassis 110 and a movable drive component 126. A motorized drive component 124 is located between the two drive components 122 and 126, which, when actuated accordingly, ensures that the movable drive component 126 is moved relative to the chassis 110 along a direction of movement 126a. The direction of movement 126a runs parallel to a y-direction. A corresponding Cartesian coordinate system is shown in the bottom right of FIG. 1.

The movable drive component 126 is also referred to in this document as a gripper because, as explained in detail below, it is designed to selectively grip individual component feeders and move them along the y-axis (to the left in FIG. 1).

As can be seen from FIG. 1, according to the exemplary embodiment shown here, four coupling devices are attached to the movable drive component or to the gripper 126, a first coupling device 130a, a second coupling device 130b, a third coupling device 130c and a fourth coupling device 130d. The coupling devices 130a to 130d each have an actuator and a coupling element, but these are not shown in FIG. 1.

The handling device 100 further comprises a control device 102, which is communicatively connected both to the motorized drive component 124 and to the four coupling devices 130a to 130d. Via corresponding communication signals, the control device 102 controls the operation of the handling device 100 at least with respect to the motorized components essential for the embodiment described here, i.e. with respect to the motorized drive component 124 of the drive 120 and to the four coupling devices 130a to 130d.

The coupling elements of the four coupling devices 130a to 130d, which are not shown, are designed in such a way that, when the respectively assigned actuator is actuated, a respective component feeder is mechanically connected to the movable drive component 126, provided that it is in contact or can be contacted with the respective coupling device. This connection or coupling is shown in FIG. 1 in an operating state of the handling device 100, in which four component feeders are connected to the movable drive component or the gripper 126. Specifically, in the operating state shown here, a first component feeder 190a is connected to the gripper 126 via the first coupling device 130a. Furthermore, as can be seen in FIG. 1, a second component feeder 190b is connected to the gripper 126 via the second coupling device 130b and a third component feeder 190c is connected to the gripper 126 via the third coupling device 130c. No component feeder is connected to the fourth coupling device 130d according to the operating state shown here. The coupling interfaces between in each case one component feeder and one coupling device are shown in FIG. 1 with the reference numeral 131.

FIG. 1 shows the handling device in an operating state in which the gripper 126 is in its retracted state in relation to the chassis 110. In FIG. 1, this means that the gripper 126 is in its right end position. Previously, the gripper 126 was in its extended position, in which the distance to the stationary drive component 122 is significantly greater than in FIG. 1. In this extended position, all four coupling devices 130a to 130d were each in contact or at least mechanically contactable with a component feeder (not shown), which was located in a component feed system of a pick and place station, which is also not shown. Before moving the gripper 126 back into its retracted state, only the three coupling devices 130a, 130b and 130c were activated, so that only the three “old” component feeders 190a, 190b and 190c were “taken along” or removed from the component feeder on the path of the gripper 126 back into its retracted state. The feed tracks thus freed up can then be filled with “new” component feeders.

FIG. 2 shows a perspective view of details of the coupling devices of a handling device for handling a maximum of ten component feeders (not shown). The movable drive component or the gripper 126 is shown with a number of technical details which are of no further significance for the invention described in this document. According to the exemplary embodiment shown here, the various coupling devices, here ten in number, are combined to form a coupling system, which is provided with the reference numerals 230.

The coupling system 230 has a housing 231 in which the total of ten coupling devices are accommodated. Their total of ten actuators 232 are arranged along a row parallel to an x-direction. A coupling element 234 is located underneath each of the actuators 232. In the front area on their underside, the coupling elements 234 each have a recess 234a, which can be mechanically brought into engagement with a complementary engagement structure in the respective component feeder (not shown). This mechanical engagement takes place via actuation by the respective associated actuator 232.

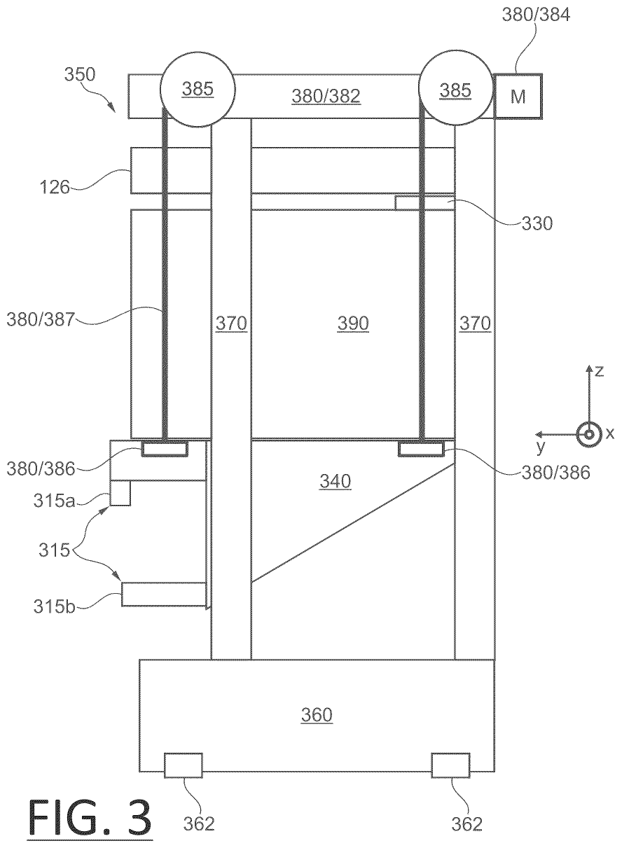

FIG. 3 shows a robotic system 350 according to an exemplary embodiment of the invention. The robotic system 350 has a driverless transport vehicle 360. On the underside of the driverless transport vehicle 360, there are a plurality of wheels 362 in a known manner with which the driverless transport vehicle 360 can travel along any spatial direction, for example on the floor of a factory. For example, the driverless transport vehicle 360 can move the entire robotic system 350 from a temporary storage area for component feeders to a pick and place station at which at least one component feeder is to be replaced, and back to the temporary storage area.

According to the exemplary embodiment shown here, a mechanical support structure 370 extends upwards from the driverless transport vehicle 360.

The mechanical support structure 370 represents a frame structure to which a number of parts of the robotic system 350, some of which are not shown, are attached.

The robotic system 350 further comprises a handling device described above for automatically exchanging component feeders. In the side view shown here (the drawing plane is spanned by the y-direction and the vertical z-direction), only a single engaged component feeder 390 and the corresponding coupling device 330 can be recognized. In particular, it cannot be seen in this view that there are several such coupling devices 330 on the movable drive component or the gripper 126, each of which is configured to mechanically connect a component feeder 390 to the gripper 126.

In addition to the gripper 126 shown here together with the coupling devices 330 attached to it, the handling device has a support structure 340 designed as a support table. The support table 340 and gripper 126 are connected to each other in a spatially fixed manner, as not shown. The component feeders 390 are displaced along the y-direction on the surface of the support structure 340 during operation of the robotic system 350 or the handling device. In the process, the pertaining component feeder 390 slides or glides along this surface. According to the exemplary embodiment shown here, a guiding structure not shown, implemented by a rail, is used to displace the pertaining component feeder 390 along a precisely defined displacement path along the y-direction.

The robotic system 350 shown in FIG. 3 also has a vertical drive 380. According to the exemplary embodiment shown here, the vertical drive 380 comprises a stationary vertical drive component 382 attached to the mechanical support structure 370 and a movable vertical drive component 386 attached to the handling device, which is displaceable relative to the stationary vertical drive component 382 along the vertical z-direction. As can be seen from FIG. 3, the movable vertical drive component 386 is multi-piece and comprises a plurality of attachment blocks which are connected to the support table 340 or embedded in the support table 340.

The vertical drive 380 further comprises a motorized vertical drive component 384. According to the exemplary embodiment shown here, this motorized vertical drive component 384 is an electric motor M, which has a plurality of pulleys 385, on each of which a traction cable 387 is wound. In the side view of FIG. 3, only two of the total of four pulleys 385 and the associated traction cables 387 can be seen. In reality, there are exactly four traction cables 387 in the exemplary embodiments shown here, each of which holds the support table 340 at one corner.

By suitable control of the motorized vertical drive component 384, for example by the control device 102 shown in FIG. 1, the height position of the support table 340 and thus the height position of the entire handling device can be set so that this height position corresponds exactly to the height position in which the pertaining component feeder 390 is to be transferred to a component feed system of a pick and place station by a purely linear movement along the y-direction. The same applies accordingly to a transfer of an “old” component feeder 390 from the pick and place station or from its component feed system to the handling device.

As can be seen from FIG. 3, the robotic system 350 also has a positioning device 315, which is attached to or formed on the support table 340. The positioning device 315 is designed such that it (only) interacts with a complementary positioning device of the pick and place station or of the component feed system when the handling device is correctly positioned in relation to a pick and place station not shown or, more precisely, in relation to a component feed system of a pick and place station that is also not shown. This ensures correct positioning of the handling device for reliable exchanging of an “old” component feeder with a “new” component feeder.

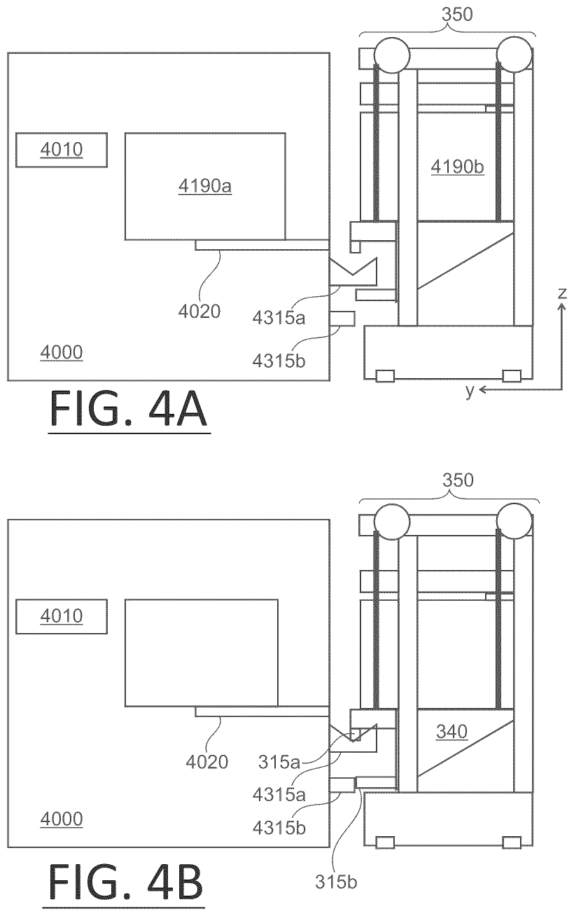

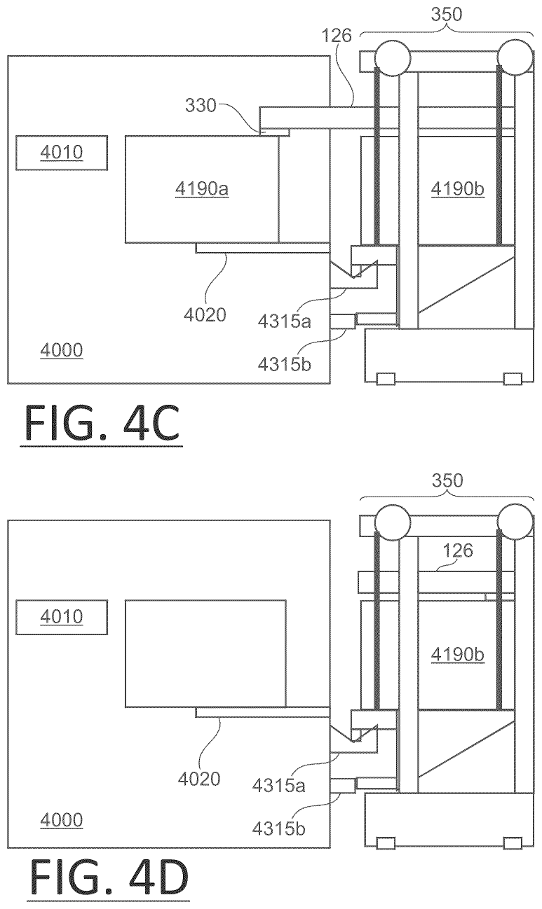

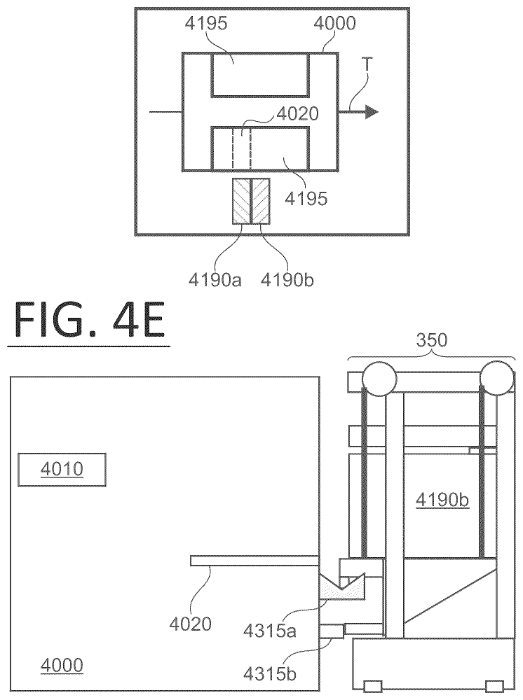

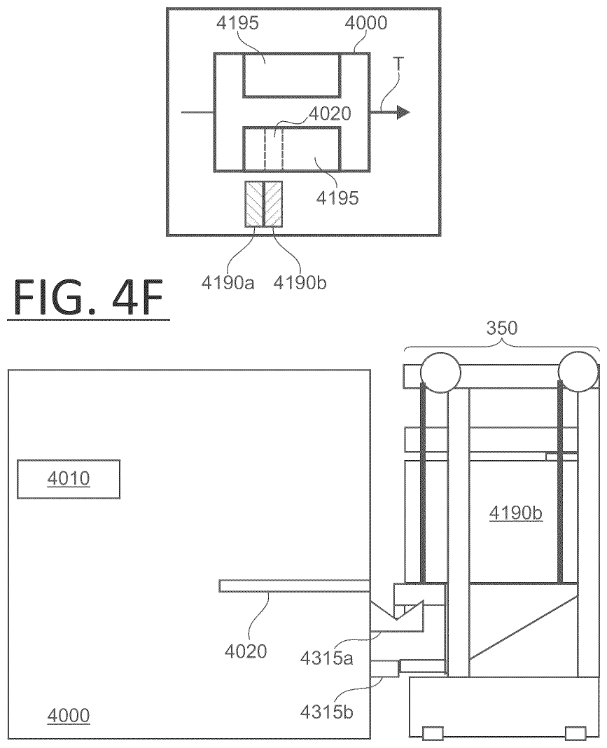

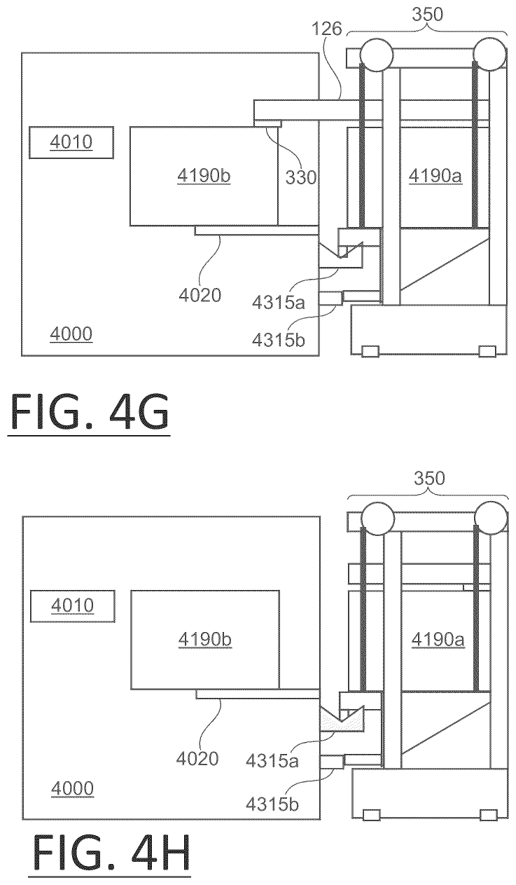

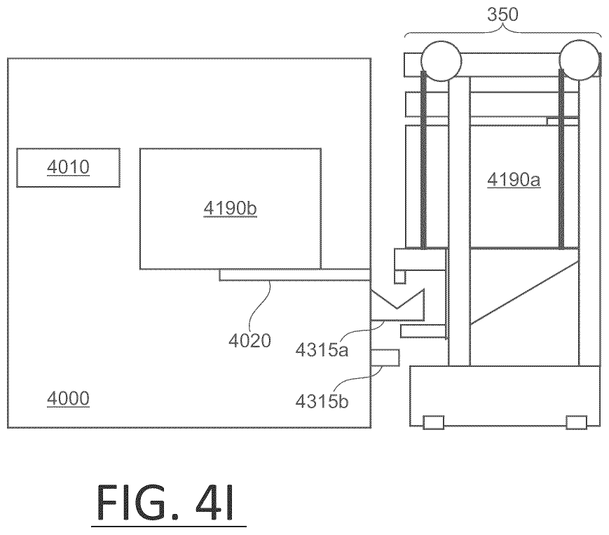

According to the exemplary embodiment shown here, the positioning device 315 is equipped with an engagement element 315a and a stop element 315b. When the robotic system 350 is correctly positioned, these come into engagement or mechanical contact with a corresponding complementary engagement element or a corresponding complementary stop element on the side of the pick and place station or its component feed system. Exemplary embodiments of these complementary elements are shown in FIGS. 4a to 4i and are briefly explained with reference to these figures.

FIGS. 4a to 4i illustrate the various steps involved in exchanging an “old” component feeder 4190a with a “new” component feeder 4190b. In all these figures, the pick and place station from which the “old” component feeder 4190a is removed and into which the “new” component feeder 4190b is inserted is identified by the reference numeral 4000.

The pick and place station 4000 has a transport device 4010 for component carriers not shown. The component carriers to be assembled are moved into a placement area of the pick and place station 4000 by means of the transport device 4010 in a known manner and the at least partially assembled component carriers are moved out of this assembly area by means of the transport device 4010 in a likewise known manner. The component carriers are transported along an x-direction, which is perpendicular to the drawing plane, which is spanned by the y-direction and the z-direction.

The pick and place station 4000 is equipped with the component feed system already mentioned above. This comprises several feed tracks 4020 for receiving a component feeder in each case. In the sectional views of FIGS. 4a to 4i, only one feed track 4020 can be seen in each case.

The pick and place station 4000, or more precisely its component feed system, has the elements of the complementary positioning device already described above. These elements are a complementary engagement element 4315a and a complementary stop element 4315b.

The exchanging of the “old” component feeder 4190a with the “new” component feeder 4190b begins with the robotic system being moved towards the pick and place station 4000. The final state of this “approach” is shown in FIG. 4a.

The vertical drive 380 of the robotic system 350 is then activated such that the support table 340 is lowered such that the engagement element 315a of the robotic system 350 engages with the complementary engagement element 4315a of the pick and place station 4000. The lowered state is shown in FIG. 4b. In this lowered state, the stop element 315b of the robotic system 350 is in contact with the complementary stop element 4315b of the pick and place station 4000. The mechanical contact shown here between the two engagement elements 315a and 4315a and the mechanical contact between the two stop elements 315b and 4315b ensures correct positioning of the robotic system 350 relative to the pick and place station along the y-direction and along the x-direction perpendicular to the drawing plane. The engagement between the two engagement elements 315a and 4315a also ensures correct height positioning of the handling device or the support table 340 of the handling device.

In a next step, shown in FIG. 4c, the gripper 126 (together with all coupling devices 330) is moved out of the handling device. In the sectional view of FIG. 4c, again only one coupling device 330 can be seen. This is activated by “its” actuator, which is not shown, such that it engages the “old” component feeder 4190a and thereby connects it to the gripper 126.

Then, as shown in FIG. 4d, the gripper 126 is moved back into its retracted position and the “old” component feeder 4190a is pulled into the handling device. In FIG. 4d, the “old” component feeder 4190a is located behind the “new” component feeder 4190b and is therefore no longer visible in this FIG. 4d.

The robotic system 350 is then moved along the x-direction out of the drawing plane by a small distance to such an extent that the “new” component feeder 4190b is now aligned with the feed track 4020 instead of the “old” component feeder 4190a. This “side step” of the robotic system 350 is shown in FIG. 4e and FIG. 4f. These two figures each show a top view in which (i) the pick and place station 4000 (with two component feed systems 4195 on both sides of the transport device 4010) and (ii) the component feeders 4190a and 4190b involved are shown in a plan view. Here, the transport direction of the component carriers is indicated by the arrow “T”.

After this “side step”, the coupling device 330 that is assigned to the “new” component feeder 4190b is activated first. The gripper 126 is then moved out again and the “new” component feeder 4190b is inserted into the pick and place station 4000 or its component feed system. This state is shown in FIG. 4g.

In a next step, the coupling between the “new” component feeder 4190b and its associated coupling device 330 is canceled and the gripper 126 is moved back to its initial position. This state is shown in FIG. 4h.

Before the “old” component feeder 4190a can be returned to a temporary storage location not shown, the mechanical coupling between the robotic system 350 and the pick and place station 4000 must be removed. For this purpose, the support table 340 is raised by activating the vertical drive 380 accordingly, thus releasing the engagement, in particular between the engagement element 315a of the robotic system 350 and the complementary engagement element 4315a of the pick and place station 4000. This decoupled state is shown in FIG. 4i.

It is noted that the term “have” does not exclude other elements and that the word “one or a” does not exclude a plurality. Elements, which are described in connection with different exemplified embodiments, can also be combined. It should also be noted that reference signs in the claims should not be construed as limiting the scope of the claims.

### REFERENCE SIGNS

100 Handling device
102 Control device
110 Chassis
120 Drive
122 Stationary drive component
124 Motorized drive component
126 Movable drive component/gripper
126a Direction of movement
130a First coupling device
130b Second coupling device
130c Third coupling device
130d Fourth coupling device
131 Coupling interfaces
190a First component feeder
190b Second component feeder
190c Third component feeder
230 Coupling system
231 Coupling housing
232 Actuators
234 Coupling elements
234a Recesses
315 Positioning device
315a Engagement element
315b Stop element
330 Coupling device
340 Support structure/support table
350 Robotic system
360 Driverless transport vehicle
362 Wheels
370 Mechanical support structure
380 Vertical drive
382 Stationary vertical drive component
384 Motorized vertical drive component
385 Pulleys
386 Movable vertical drive component
387 Coupling structure/Traction cable
390 Component feeder
4000 Pick and place station
4010 Transport device for component carrier
4020 Feed track
4190a “Old” component feeder
4190b “New” component feeder
4195 Component feed system
4315a Complementary engagement element
4315b Complementary stop element
T Transport direction of component carrier LISTING OF THE CLAIMS

1. A handling device for automatically exchanging component feeders at a pick and place station for automatically placing electronic components on component carriers, the handling device comprising a chassis;
a drive with a stationary drive component attached to the chassis and a movable drive component which can be spatially positioned along a y-direction;
a first coupling device, which is attached to the movable drive component and which comprises a first coupling element and a first actuator;
a second coupling device, which is also attached to the movable drive component and which comprises a second coupling element and a second actuator; and
a control device configured to individually actuate the first actuator and to individually actuate the second actuator; wherein
the first coupling element is arranged to couple to a first component feeder when the first actuator is actuated, and wherein the second coupling element is arranged to couple with a second component feeder when the second actuator is actuated.

2. The handling device according to claim 1, wherein
the first coupling element comprises a first engagement element configured to be engaged by the first actuator with a complementary first engagement element on the first component feeder (190a) and
the second coupling element comprises a second engagement element configured to be engaged by the second actuator with a complementary second engagement element on the second component feeder (190b).

3. The handling device according to claim 1, wherein
the coupling devices are arranged next to one another along an x-direction, the x-direction being angular and in particular perpendicular to the y-direction.

4. The handling device according to claim 1, wherein
the drive further comprises a movable intermediate component which, together with the stationary drive component and the movable drive component, forms a telescopic system.

5. The handling device according to claim 1,
wherein the first coupling device further comprises a further first coupling element which is spatially spaced along the y-direction from the first coupling element, wherein the further first coupling element is configured to couple (i) upon an actuation of the first actuator or (ii) upon an actuation of a further first actuator of the first coupling device with the first component feeder, and/or
wherein the second coupling device further comprises a further second coupling element which is spatially spaced along the y-direction from the second coupling element, wherein the further second coupling element is configured to couple (i) upon actuation of the second actuator or (ii) upon actuation of a further second actuator of the second coupling device to the second component feeder.

6. The handling device according to claim 1, further comprising a third coupling device (130c), which is also attached to the movable drive component and which comprises a third coupling element and a third actuator; wherein
the control device is further configured to individually actuate the third actuator; wherein
the third coupling element is configured to couple to a third component feeder upon actuation of the third actuator.

7. The handling device according to claim 1, further comprising
a support structure for supporting the first component feeder and/or the second component feeder (190b).

8. A robotic system comprising
a driverless transport vehicle;
a mechanical support structure, attached to the driverless transport vehicle; and
a handling device according tom claim 1, which is attached to the mechanical support structure.

9. The robotic system according to claim 8, further comprising
a vertical drive having a stationary vertical drive component attached to the mechanical support structure and a movable vertical drive component attached to the handling device which is displaceable relative to the stationary vertical drive component along a vertical z-direction.

10. The robotic system according to claim 8,
wherein the vertical drive further comprises a motorized vertical drive component and
wherein the movable vertical drive component comprises a coupling structure via which the movable vertical drive component is coupled to the motorized vertical drive component.

11. The robotic system according to claim 10, wherein
the coupling structure comprises at least one support rod and/or at least one traction cable.

12. The robotic system according to claim 8, further comprising
a positioning device, which is attached directly or indirectly to the chassis of the handling device and which is designed such that it interacts with a complementary positioning device of the pick and place station when the handling device is correctly positioned in relation to a pick and place station.

13. The robotic system according to claim 12, wherein
the positioning device and the complementary positioning device comprise mechanical positioning elements (315a, 315b; 4315a, 4315b) which come into mechanical contact and/or engagement with one another when the handling device is correctly positioned.
